(19) United States
(12) Patent Application Publication
(10) Pub. No.: US 2024/0258170 A1
(43) Pub. Date: Aug. 1, 2024

(54) METHOD OF MANUFACTURING SEMICONDUCTOR ELEMENT

(71) Applicant: NICHIA CORPORATION, Anan-shi (JP)

(72) Inventors: Minoru YAMAMOTO, Anan-shi (JP); Naoto INOUE, Anan-shi (JP); Masayuki IBARAKI, Anan-shi (JP); Hiroaki TAMEMOTO, Anan-shi (JP)

(73) Assignee: NICHIA CORPORATION, Anan-shi (JP)

(21) Appl. No.: 18/422,925

(22) Filed: Jan. 25, 2024

(30) Foreign Application Priority Data
Jan. 27, 2023 (JP) 2023-011277
Aug. 22, 2023 (JP) 2023-134747

(51) Int. Cl. H01L 21/78; H01L 21/428

(52) U.S. Cl. CPC H01L 21/78; H01L 21/428

(57) ABSTRACT

A method of manufacturing a semiconductor element includes irradiating a laser beam on a wafer, which includes a sapphire substrate having a first face and a second face opposite the first face and a semiconductor structure disposed on the first face, from a second face side. The laser beam irradiated along a first direction parallel to the second face of the sapphire substrate is focused inside the sapphire substrate to thereby create a modified portion in the sapphire substrate along the first direction. The wafer is severed and separated into a number of semiconductor elements following the formation of a modified portion. In the step of forming a modified portion, the laser beam is focused closer to the second face than to the first face in a thickness direction of the sapphire substrate.

### CROSS-REFERENCE TO RELATED APPLICATIONS

This application claims priority to Japanese Patent Application No. 2023-011277, filed on Jan. 27, 2023, and Japanese Patent Application No. 2023-134747, filed on Aug. 22, 2023. The entire contents of these applications are incorporated by reference herein.

### BACKGROUND

The present disclosure relates to a method of manufacturing a semiconductor element.

A semiconductor element can be produced by dicing a wafer composed of a substrate and semiconductor layers formed on the substrate. Japanese Patent Publication No. 2022-18505 discloses a method of dicing a wafer in which a laser beam is focused inside the substrate to form modified portions, and the wafer is separated into a number of semiconductor chips by utilizing cracks propagating from the modified portions. However, cracks can occasionally develop in an unintended direction because of the crystal structure of the wafer, making it difficult to achieve a desired shape for the semiconductor chips.

### SUMMARY

One object of the present invention is to provide a method of manufacturing a semiconductor element that can achieve a desired semiconductor element shape.

According to one implementation of the present disclosure, a wafer composed of a sapphire substrate having a first face and a second face opposite the first face and a semiconductor structure disposed on the first face is subjected to laser beam irradiation from the second face side. The laser beam scanned along the first direction parallel to the second face of the sapphire substrate is focused inside the sapphire substrate to thereby create modified portions in the sapphire substrate along the first direction. The wafer is severed and separated into a number of semiconductor elements after forming a modified portion. In the step of forming a modified portion, the laser beam is focused to a position in the direction of thickness of the sapphire substrate that is closer to the second face than to the first face. The sapphire substrate has a crystal structure which includes a plurality of crystal planes along (10-14) or (10-11) planes. The intensity distribution of the laser beam has the intensity peak in the first face of the sapphire substrate that is shifted from the center of the intensity distribution of the laser beam in a second direction that intersects the first direction. The second direction, in a plan view, is a direction from a given first point on the first intersecting line where the first face meets a third face along one of the plurality of crystal planes that is closest to being in parallel with the first direction towards a given second point on the second intersecting line where the third face meets the second face.

A method of manufacturing a semiconductor element according to the present invention can achieve a desired semiconductor element shape.

### BRIEF DESCRIPTION OF THE DRAWINGS

FIG. 1 is a schematic plan view of a wafer according to an embodiment.

FIG. 2 is a schematic cross-sectional view of the wafer according to the embodiment.

FIG. 3A is a schematic cross-sectional view explaining a laser irradiation step in a method of manufacturing a semiconductor element according to an embodiment.

FIG. 3B is a schematic plan view explaining the laser irradiation step in the method of manufacturing a semiconductor element according to the embodiment.

FIG. 4A is a schematic cross-sectional view explaining a manufacturing method according to a first embodiment.

FIG. 4B are perspective views schematically showing the crystal structure of a wafer according to the first embodiment.

FIG. 5A is a schematic cross-sectional view explaining the manufacturing method according to the first embodiment.

FIG. 5B is a schematic plan view explaining the manufacturing method according to the first embodiment.

FIG. 5C is a schematic diagram explaining the manufacturing method according to the first embodiment.

FIG. 6A is a schematic diagram of the crystal structure of the wafer according to the first embodiment.

FIG. 6B is a schematic plan view explaining the manufacturing method according to the first embodiment.

FIG. 7A is a schematic plan view explaining the manufacturing method according to the first embodiment.

FIG. 7B is a schematic diagram of the crystal structure of the wafer according to the first embodiment.

FIG. 8 is a graph showing the laser irradiation characteristics in the manufacturing method according to the first embodiment.

FIG. 9A is a schematic diagram explaining a manufacturing method according to a second embodiment.

FIG. 9B is a schematic diagram of the crystal structure of a wafer according to the second embodiment.

FIG. 10 is a graph showing the laser irradiation characteristics in the manufacturing method according to the second embodiment.

FIG. 11A is a schematic diagram explaining a manufacturing method according to a third embodiment.

FIG. 11B is a schematic diagram of the crystal structure of a wafer according to the third embodiment.

### DETAILED DESCRIPTION

Certain embodiments will be explained below with reference to the accompanying drawings. In the drawings, the same constituents are denoted by the same reference numerals.

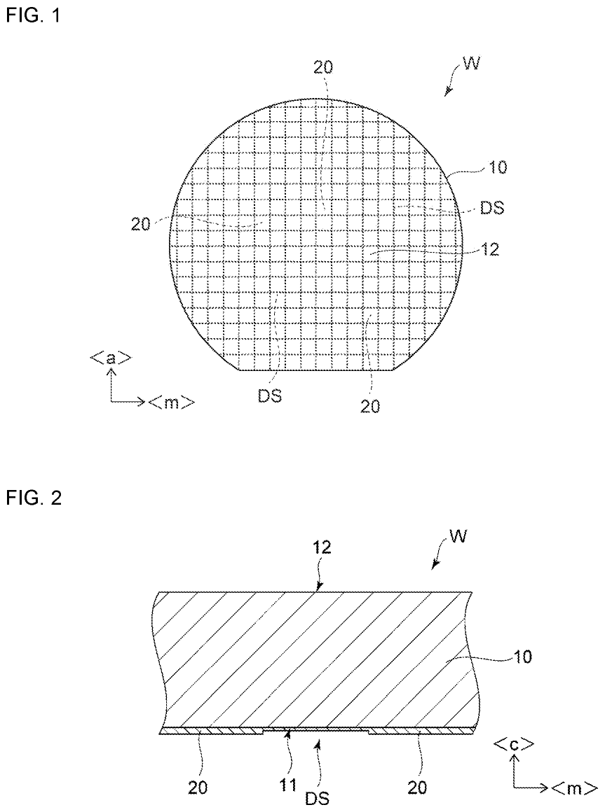

FIG. 1 is a schematic plan view of a wafer W according to an embodiment. FIG. 2 is a schematic cross-sectional view of a portion of the wafer W where a dicing street DS is located.

The wafer W has a sapphire substrate 10 and a semiconductor structure 20. The sapphire substrate 10 has a first face 11 and a second face 12 opposite the first face 11. The semiconductor structure 20 is disposed on the first face 11 of the sapphire substrate 10.

The sapphire substrate 10 has a hexagonal crystal structure, and the first face 11, for example, is a C plane. The first face 11 may be oblique to the C plane to improve the crystallinity of each semiconductor layer of the semiconductor structure 20 epitaxially grown.

The semiconductor structure 20 includes, for example, a nitride semiconductor expressed by the compositional formula InₓAl_{y}Ga_{1-x-y}N (0≤x, 0≤y, x+y<1). The semiconductor structure 20 is, for example, a light emitting diode or transistor.

Severing the wafer W along the dicing streets DS produces a number of semiconductor elements. In a plan view, dicing streets DS are arranged in a matrix on the wafer W, for example. The dicing streets DS extend, for example, in the a-axis direction and m-axis direction of the sapphire substrate 10. Singulated semiconductor elements each have a semiconductor structure 20.

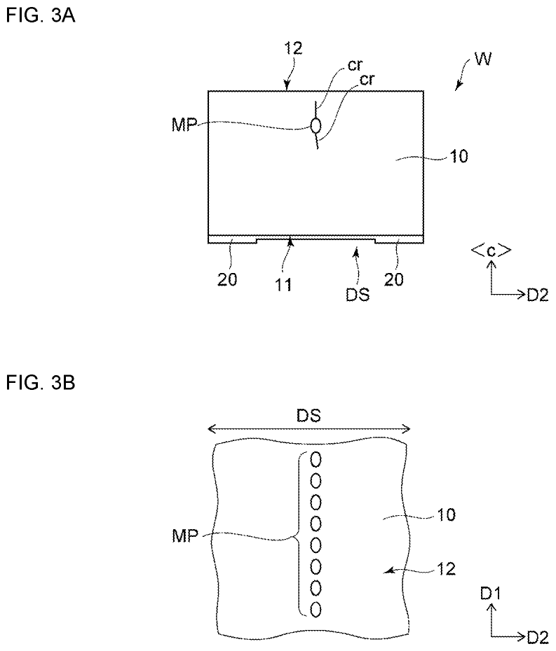

In a method of manufacturing a semiconductor element according to an embodiment, a laser beam is irradiated on a wafer W having a sapphire substrate 10 and a semiconductor structure 20 to thereby form a modified portion MP (see FIG. 3A) inside the sapphire substrate 10. The laser beam which is irradiated from the second face 12 side of the sapphire substrate 10 is scanned along the dicing streets DS. The laser beam is focused inside the sapphire substrate 10, forming a modified portion where the laser beam is focused.

The laser beam is first scanned along the dicing streets DS extending in one of the a-axis and m-axis directions shown in FIG. 1, and then scanned along the dicing streets DS extending in the other direction.

The laser source is operated in pulsed mode, for example, and the laser beam is scanned in pulsed operations. The pulse width of the laser beam is, for example, 100 fs to 1000 ps.

For the laser source, for example, Yb:YAG laser, titanium sapphire laser, Yb:YVO4 laser, Nd:YLF laser, or the like may be used. The peak wavelength of the laser beam is, for example, 500 nm to 1200 nm. The sapphire substrate 10 has a high light transmittance with respect to the peak wavelength of the laser beam described above, but a portion of the laser beam is absorbed by the sapphire substrate 10.

FIG. 3A is a schematic cross-sectional view explaining a laser irradiation step according to an embodiment.

FIG. 3B is a schematic plan view explaining the laser irradiation step according to the embodiment.

In FIG. 3A and FIG. 3B, one of the laser scanning directions is the first direction D1. The first direction D1 parallels the second face 12 of the sapphire substrate 10. In the case of scanning the laser beam along the a-axis shown in FIG. 1, the first direction D1 parallels the a-axis. In the case of scanning the laser beam along the m-axis shown in FIG. 1, the first direction D1 parallels the m-axis. The scanning direction intersecting the first direction D1 is designated as a second direction D2. For example, the second direction D2 is orthogonal to the first direction D1. For example, the first direction D1 can be in parallel with the a-axis and the second direction D2 can be in parallel with the m-axis.

For example, the laser beam is irradiated on the sapphire substrate 10 from the second face 12 of the sapphire substrate 10. The laser beam is focused inside the sapphire substrate 10 at a predetermined depth, where the laser beam energy is concentrated. This forms a modified portion MP at the position where the laser beam is focused inside the sapphire substrate 10. A modified portion MP is a portion of the sapphire substrate 10 that is more brittle than the other portion that is not hit by a laser beam. The laser beam output is preferably 0.1 μJ to 20.0 μJ, for example, more preferably 1.0 μJ to 15.0 μJ, even more preferably 2.0 μJ to 10.0 μJ.

As shown in FIG. 3A, a modified portion MP is preferably formed at a position that is near the second face 12 of the sapphire substrate 10. The modified portion MP is formed by focusing the laser beam inside the sapphire substrate 10 closer to the second face 12 than to the first face in the direction of thickness, i.e., in the direction parallel to the c-axis of the sapphire substrate 10 (hereinafter the c-axis direction). In other words, in the c-axis direction, the distance between a modified portion MP and the second face 12 is smaller than the distance between the modified portion MP and the first face 11. This can reduce the impact of the laser irradiation on the semiconductor structure 20 disposed on the first face 11.

Forming a modified portion MP inside the sapphire substrate 10 distorts the area around the modified portion MP. The distortion disappears when a crack cr extends from the modified portion MP. A crack cr extends, for example, from a modified portion MP towards the first face 11 and the second face 12 of the sapphire substrate 10 providing a starting point for severing the sapphire substrate 10.

As shown in FIG. 3B, the laser beam irradiation position is moved along the first direction D1 in the dicing streets DC. The first direction D1 is one of the two directions in which the dicing streets DS extend. A number of modified portions MP aligned along the first direction D1 are formed inside the sapphire substrate 10 by the laser beam emitted from a pulsed laser source. The modified portions MP are formed, for example, along the first direction D1. The modified portions MP may be apart from one another, for example, or those that are adjacent to one another may be in contact with or overlapping one another in the first direction D1. For example, modified portions MP may be formed to overlap to form a continuous line extending in the first direction D1.

### First Embodiment

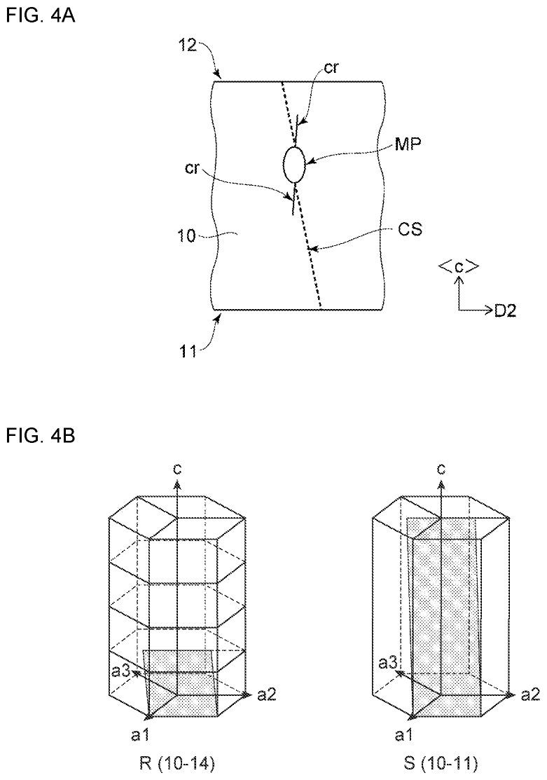

FIG. 4A is a schematic cross-sectional view explaining a manufacturing method according to a first embodiment.

FIG. 4B are perspective views schematically showing the crystal planes CS of the sapphire substrate 10 shown in FIG. 4A.

As shown in FIG. 4A, the sapphire substrate 10 has crystal planes CS attributed to its crystal structure. The crystal planes CS affect more greatly the direction in which a crack cr extends from a modified portion MP than the other crystal planes in the crystal structure of the sapphire substrate 10. A crack cr extending from a modified portion MP affected by a crystal plane CS tends to extend in the direction along the crystal plane CS, making the sapphire substrate 10 prone to fracturing in the direction along the crystal plane CS.

In the case of severing a wafer W having a sapphire substrate 10 and a semiconductor structure 20 into a number of semiconductor elements, the sapphire substrate 10 is preferably severed along planes that include the c-axis and the directions in which the dicing streets DC extend. The sapphire substrate 10 of a semiconductor element preferably has a shape approximating a cube in which each lateral face of the sapphire substrate 10 is orthogonal to the first face 11 or the second face 12, for example. If the sapphire substrate 10 is severed along the crystal planes CS oblique to the c-axis, the lateral faces of the sapphire substrate 10 of each semiconductor element after singulation would be oblique to the first face 11 or the second face 12, making it difficult to obtain a desired shape of the sapphire substrate 10. Accordingly, a laser beam is desirably irradiated such that cracks cr extend from modified portions MP along the c-axis direction.

FIG. 4B shows the planes (10-14) and (10-11) of the sapphire substrate. Hereinbelow, the planes (10-14) and planes equivalent thereto will be described as R-planes, and the planes (10-11) and planes equivalent thereto as S-Planes.

A sapphire substrate 10 having a crystal plane perpendicular to the c-axis (hereinafter C-plane) as a principal plane tends to fracture easily along R-planes, S-planes, and their composite planes, for example. Accordingly, the laser beam is preferably irradiated such that cracks cr do not extend from modified portions MP along the R-planes or S-planes.

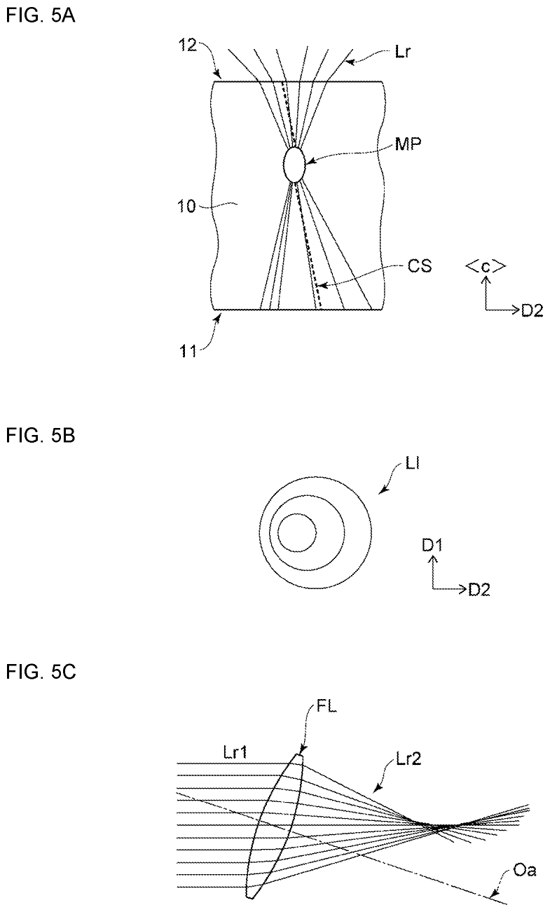

FIG. 5A is a schematic cross-sectional view explaining a laser irradiation method according to the first embodiment.

FIG. 5B is a schematic plan view explaining the laser irradiation method according to the first embodiment.

FIG. 5C is a schematic diagram explaining the laser irradiation method according to the first embodiment.

FIG. 5A schematically shows light rays Lr of the laser beam irradiated on the sapphire substrate 10. A modified portion MP is formed by focusing the laser beam inside the sapphire substrate 10. The laser beam irradiated from the second face 12 side propagates through the sapphire substrate 10 and reaches the first face 11.

FIG. 5B shows the intensity distribution LI of the laser beam in the first face 11 irradiated from the second face 12 side of the sapphire substrate 10. In the intensity distribution LI, the intensity along the inner line is higher than the intensity along the outer line. In other words, the intensity distribution LI indicates that the presence of a higher intensity peak on the inner side than the outer side.

The laser beam is irradiated in the state in which the intensity peak of the laser beam is off-centered as in the case of the intensity distribution LI shown in FIG. 5B. The off-centering direction of the intensity peak is, for example, a direction in which a crystal plane CS is oblique to the c-axis. In this example, the intensity peak off-centering direction is opposite the second direction D2, but the embodiment is not limited to this.

As shown in FIG. 5C, a focusing lens FL is positioned such that the central axis Oa of the focusing lens FL is oblique to the light rays Lr1 of the laser beam on the incident side. Accordingly, the light rays Lr2 that passed through the focusing lens FL are not converged at one point, but are collected to generate so-called comatic aberration. This achieves the state in which the intensity peak of the laser beam in the first face 11 of the sapphire substrate 10 is off-centered. The intensity peak off-centering direction and degree are controlled by the oblique angle of the central axis Oa of the focusing lens FL. The method of controlling the laser beam in any embodiment of the invention is not limited to using the focusing lens FL shown in the drawing, and may be any method that generates comatic aberration. For example, the laser beam can be controlled by using a liquid crystal on silicon spatial light modulator (LCOS SLM).

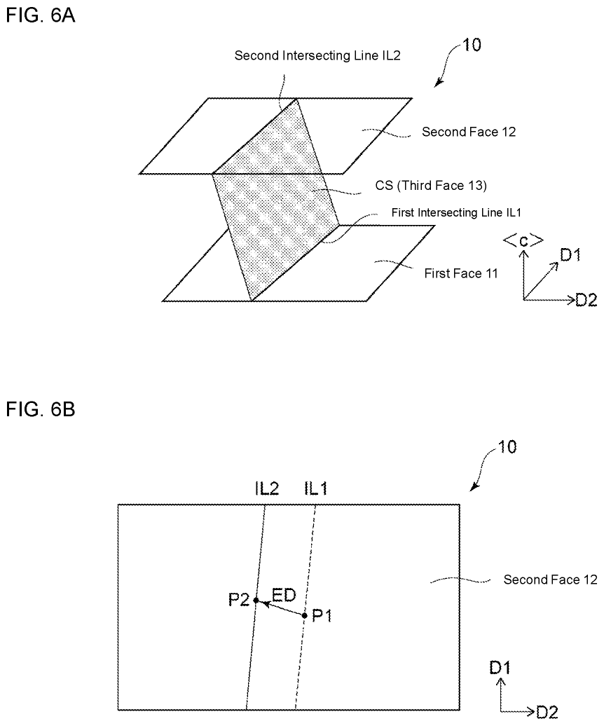

FIG. 6A is a schematic diagram of a crystal plane CS of the sapphire substrate 10.

FIG. 6B is a schematic plan view explaining the manufacturing method according to the first embodiment. FIG. 6B shows the first intersecting line IL1 and the second intersecting line IL2 in the plan view.

As shown in FIG. 6A, a crystal plane CS of the sapphire substrate 10 intersects the first face 11 and the second face 12. The face along the crystal plane CS among multiple crystal planes CS that is closest to being in parallel with the first direction D1 is designated as a third face 13. The face along the crystal plane CS among multiple crystal planes CS that forms the smallest angle with the first direction D1 is designated as a third face 13. In the following description, the intersecting line where a third face 13 meets the first face 11 is designated as the intersecting line IL1, and the intersecting line where the third face 13 meets the second face 12 is designated as the intersecting line IL2.

For example, in a singulation step for a sapphire substrate 10 having C-plane as a principal plane, the crystal planes CS that primarily cause oblique fractures of the sapphire substrate 10 are S-planes or R-planes. In the following description, the crystal planes CS are assumed as S-planes.

FIG. 6B shows the first intersecting line IL1 and the second intersecting line IL2 of a third face 13. When scanning a laser beam along the first direction D1, the intensity peak of the laser beam in the first face 11 is shifted from the center of the intensity distribution of the laser beam in the ED direction. Here, the ED direction is the direction from a given first point P1 on the first intersecting line IL1 to a given second point P2 on the second intersecting line IL2 in the plan view.

As shown in FIG. 6B, the ED direction intersects the first direction D1. The ED direction may be, for example, the direction opposite the second direction D2 that is orthogonal to the first direction D1, but is not limited to this. The ED direction is desirably selected to make it difficult for a crack cr originating from a modified portion MP (see FIG. 5A) to extend along the crystal plane CS, for example.

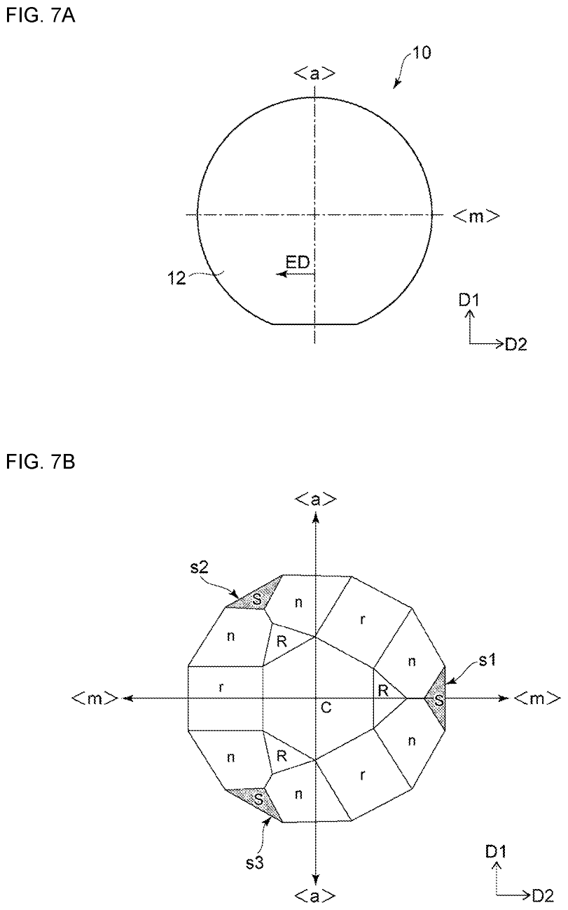

FIG. 7A is a schematic plan view explaining the manufacturing method according to the first embodiment. FIG. 7B is a schematic diagram of the crystal structure of the sapphire substrate 10. FIG. 7A shows the second face 12 of the sapphire substrate 10.

As shown in FIG. 7A, the first direction D1 parallels the a-axis (hereinafter the a-axis direction), and the second direction D2 parallels the m-axis (hereinafter the m-axis direction).

The laser beam is scanned in the first direction D1 first, and scanned in the second direction D2, for example. The laser beam having an intensity distribution in which the intensity peak is shifted in the ED direction in the first face 11 is scanned in the first direction D1. For example, the laser beam intensity distribution can be controlled by generating comatic aberration so as to shift the intensity peak of the laser beam in the first face 11 in the ED direction.

FIG. 7B shows main crystal planes of the sapphire substrate 10. There are three equivalent S-planes when the sapphire substrate 10 is viewed in the c-axis direction. In the description below, the S-plane parallel to the a-axis is designated as the first S-plane s1, while the two S-planes intersecting the a-axis are designated as the second S-plane s2 and the third S-plane s3.

In the case of severing the sapphire substrate 10 along a plane that includes the a-axis and the c-axis, for example, the laser beam is scanned in the first direction D1 to form modified portions MP aligned along the a-axis (see FIG. 3B). Then stress is applied to the sapphire substrate 10 to break it along the plane that includes the a-axis and c-axis. At this point, the crystal plane among the three S-planes that primarily causes an oblique fracture of the sapphire substrate 10 of a semiconductor element is the first S-plane s1 that forms the smallest angle or is closest to being in parallel with the first direction D1. In the description below, the crystal plane along the first S-plane s1 is designated as the third face 13.

When scanning a laser beam in the first direction D1, the ED direction in which the laser beam intensity peak is shifted is the direction from a given first point on the first intersecting line IL1 where the first face 11 of the sapphire substrate 10 meets the third face 13 towards a second point on the second intersecting line IL2 where the second face 12 meets the third face 13 (see FIG. 6B). Because the sapphire substrate 10 has a crystal structure which has linear symmetry using the m-axis as the line of symmetry, the ED direction is preferably the direction along the m-axis. In other words, the ED direction is the direction opposite the second direction D2 that is orthogonal to the first direction D1, for example.

In the case of severing the sapphire substrate 10 along a plane that includes the m-axis and the c-axis, the laser beam is scanned in the second direction D2 to form modified portions MP aligned along the m-axis (see FIG. 3B). In this case, among the three S-planes, the second S-plane s2 and third S-plane s3, which form the smallest angles or are closest to being in parallel with the first direction D1, can cause chipping of a semiconductor element. In other words, because the crystal structure of the sapphire substrate 10 has linear symmetry using the m-axis as the line of symmetry, the substrate is affected by the two crystal planes. For this reason, shifting the laser beam intensity peak in the direction that intersects the m-axis direction would easily allow a crack cr to extend along either the second S-plane s2 or the third S-plane s3. Accordingly, the laser beam intensity peak is preferably not shifted in the direction that intersects the m-axis direction. When scanning the laser beam along the m-axis direction, for example, the laser light rays are preferably collected without allowing comatic aberration to occur in the direction that intersects the m-axis direction.

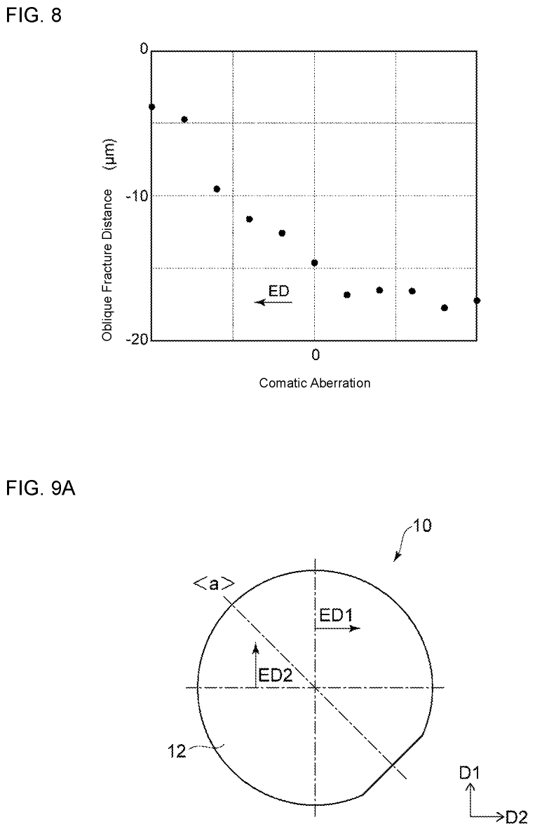

FIG. 8 is a graph showing the relationship between the amount of comatic aberration and the oblique fracture distance (μm) in the manufacturing method according to the first embodiment. The vertical axis shows the distance of fracture (μm) oblique to the c-axis, and the horizontal axis shows the amount of comatic aberration. Here, the oblique fracture distance is the distance between a modified portion MP and the position in the first face 11 reached by the crack cr obliquely extending from the modified portion MP in a top view.

As shown in FIG. 8, increasing the amount of comatic aberration in the ED direction in which the laser beam intensity peak is shifted can reduce the absolute value of the oblique fracture distance. In other words, increasing the amount of comatic aberration in the ED direction can reduce oblique fractures of the sapphire substrate 10.

### Second Embodiment

FIG. 9A is a schematic plan view explaining a manufacturing method according to a second embodiment. FIG. 9B is a schematic diagram showing the crystal structure of the sapphire substrate 10 corresponding to FIG. 9A. FIG. 9A shows the second face 12 of the sapphire substrate 10.

As shown in FIG. 9A, in this example, the first direction D1 is 45° oblique to the a-axis, and the second direction D2 is orthogonal to the first direction D1. For example, the laser beam is scanned in the first direction D1 first, and scanned in the second direction D2. In the case of scanning the laser beam along the first direction D1, the laser beam is irradiated in the state where the intensity peak is shifted from the center of the laser beam intensity distribution in the ED1 direction. In the case of scanning the laser beam along the second direction D2, the laser beam is irradiated in the state where the intensity peak is shifted from the center of the laser beam intensity distribution in the ED2 direction.

The laser beam having an intensity distribution in which the intensity peak is shifted in the ED1 direction in the first face 11 is scanned in the first direction D1. For example, comatic aberration is generated such that the intensity peak of the laser beam in the first face 11 is shifted in the ED1 direction that is orthogonal to the first direction D1.

As shown in FIG. 9B, among the three S-planes, the crystal plane which can cause chipping of a semiconductor element is the second S-plane s2 that forms the smallest angle or is closest to being in parallel with the first direction D1. In the description below, the crystal plane along the second S-plane s2 will be designated as the third a-plane 13a in this embodiment. In this case, the ED1 direction in which the intensity peak of the laser beam is shifted is the direction from a given first point on the first intersecting line IL1 where the first face 11 of the sapphire substrate 10 meets the third a-plane 13a towards a second point on the second intersecting line IL2 where the second face 12 meets the third a-plane 13a (see FIG. 6B). In this example, the ED1 direction is orthogonal to the first direction D1, i.e., the same direction as the second direction D2.

In the case of severing the sapphire substrate 10 along a plane that includes the second direction D2 and the c-axis, for example, the laser beam is scanned along the second direction D2 to form modified portions MP which are aligned along the second direction D2 (see FIG. 3B). In this case, the crystal plane that can primarily cause an oblique fracture of the sapphire substrate 10 of a semiconductor element is the third S-plane s3 which forms the smallest angle or is closest to being in parallel with the second direction D2. In the description below, the crystal plane along the third S-plane s3 will be designated as a third b-plane 13b in this embodiment.

The ED2 direction in which the intensity peak of the laser beam is shifted is the direction from a given first point on the first intersecting line IL1 where the first face 11 of the sapphire substrate 10 meets the third b-plane 13b towards a second point on the second intersecting line IL2 where the second face 12 meets the third b-plane 13b (see FIG. 6B). In this example, the ED2 direction is orthogonal to the second direction D2, i.e., the same direction as the first direction D1.

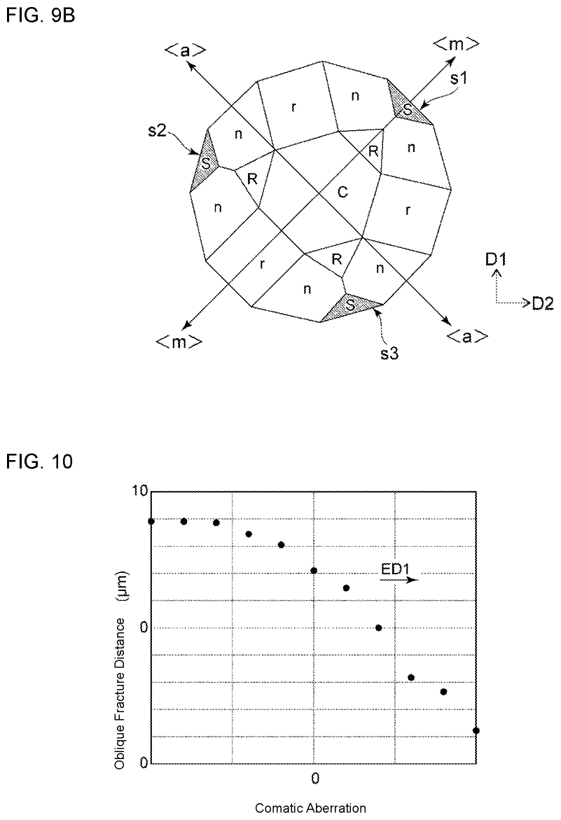

FIG. 10 is a graph showing the relationship between the amount of comatic aberration and the oblique fracture distance (μm) in the manufacturing method according to the second embodiment. The vertical axis shows the distance of oblique fracture (μm) oblique to the c-axis, and the horizontal axis shows the amount of comatic aberration. Here, the oblique fracture distance is the distance between a modified portion MP and the position in the first face 11 reached by a crack cr obliquely extending from the modified portion MP in a top view.

As shown in FIG. 10, increasing the amount of comatic aberration in the ED1 direction in which the laser beam intensity peak is shifted can reduce the oblique fracture distance. For example, when the amount of comatic aberration is increased from the zero position in the ED1 direction, the oblique fracture distance turns from positive to negative. This shows the presence of an optimal amount of comatic aberration that can achieve 0 μm oblique fracture distance.

### Third Embodiment

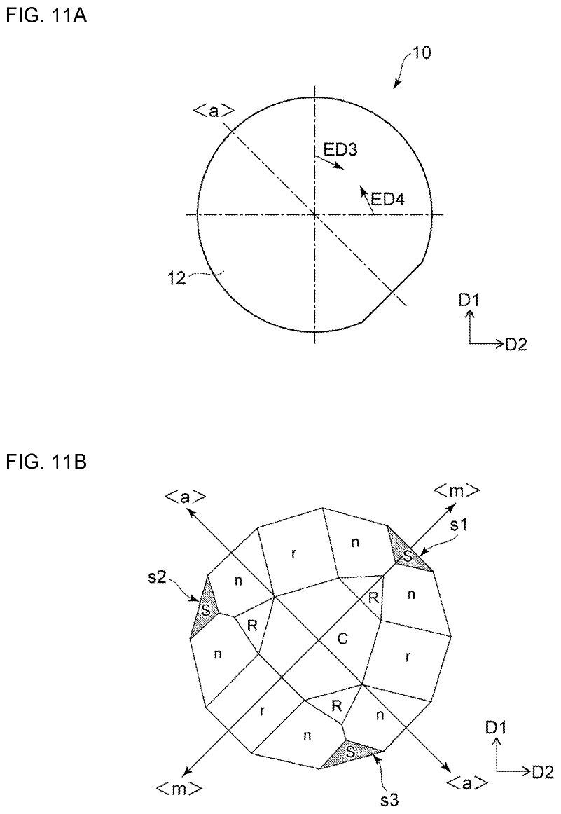

FIG. 11A is a schematic plan view explaining a manufacturing method according to a third embodiment. FIG. 11B is a schematic diagram of the crystal structure of the sapphire substrate 10 corresponding to FIG. 11A. FIG. 11A shows the second face 12 of the sapphire substrate 10. Primary differences from the second embodiment described above are such that, in the third embodiment, the ED3 direction is oblique to the first direction D1 and the ED4 direction is oblique to the second direction D2.

As shown in FIG. 11A, in this example, the first direction D1 is 45° oblique to the a-axis, and the second direction D2 is orthogonal to the first direction D1. The laser beam is scanned in the first direction D1 first, and scanned in the second direction D2, for example. In the case of scanning the laser beam along the first direction D1, the laser beam is irradiated in the state where the intensity peak in the first face 11 is shifted from the center of the intensity distribution of the laser beam in the ED3 direction. In the case of scanning the laser beam along the second direction D2, the laser beam is irradiated in the state where the intensity peak in the first face 11 is shifted from the center of the intensity distribution of the laser beam in the ED4 direction.

The laser beam having an intensity distribution in which the intensity peak in the first face 11 is shifted in the ED3 direction is scanned in the first direction D1. For example, comatic aberration is generated such that the intensity peak of the laser beam in the first face 11 is shifted in the ED3 direction that is oblique to the first direction D1.

As shown in FIG. 11B, among the three S-planes, the crystal plane that can cause chipping of a semiconductor element is the second S-plane s2 that forms the smallest angle or is closest to being in parallel with the first direction D1. In the description below, the crystal plane along the second S-plane s2 will be designated as the third a-plane 13a in this embodiment. In this case, the ED3 direction in which the intensity peak of the laser beam is shifted is the direction from a given first point on the first intersecting line IL1 where the first face 11 of the sapphire substrate 10 meets the third a-plane 13a towards a second point on the second intersecting line IL2 where the second face 12 meets the third a-plane 13a (see FIG. 6B). In this example, the ED3 direction is the direction that is orthogonal to the first intersecting line IL1 and the second intersecting line IL2.

In the case of severing the sapphire substrate 10 along a plane that includes the second direction D2 and the c-axis, the laser beam is scanned in the second direction D2 to form modified portions MP that are aligned along the second direction D2 (see FIG. 3B). In this case, among the three S-planes, the crystal plane that primarily causes an oblique fracture of the sapphire substrate 10 of a semiconductor element is the third S-plane s3 that forms the smallest angle or is closest to being in parallel with the second direction D2. In the description below, the crystal plane along the third S-plane s3 will be explained as a third b-plane 13b in this embodiment.

When scanning a laser beam in the second direction D2, the ED4 direction in which the intensity peak of the laser beam is shifted is the direction from a given first point on the first intersecting line IL1 where the first face 11 of the sapphire substrate 10 meets the third b-plane 13b towards a second point on the second intersecting line IL2 where the second face 12 meets the third b-plane 13b (see FIG. 6B). In other words, comatic aberration is generated such that the intensity peak of the laser beam in the first face 11 is shifted in the ED4 direction that is oblique to the second direction D2. In this example, the ED4 direction is the direction that is orthogonal to the first intersecting line IL1 and the second intersecting line IL2.

In the first to third embodiments described above, the direction in which the intensity peak of the laser beam in the first face 11 is shifted from the center of the intensity distribution of the laser beam was orthogonal to a laser scanning direction or the intersecting line where the first face 11 met the crystal plane CS, but the present invention is not limited to this. The off-centering direction of the laser beam intensity peak has only to intersect a scanning direction. The objective is to reduce oblique fractures of the sapphire substrate 10 in a direction that is oblique to the c-axis by suitably adjusting comatic aberration to thereby singulating light emitting elements having a desired shape.

Furthermore, in the first to third embodiments described above, cases in which modified portions MP were formed as a single line in the thickness direction of the sapphire substrate 10 have been described. However, modified portions MP may be formed along multiple lines. In this case, when forming modified portions MP along at least one line, the intensity peak of the laser beam is preferably shifted from the center of the intensity distribution of the laser beam by suitably adjusting comatic aberration or the like. This can reduce oblique fractures of the sapphire substrate 10 relative to the c-axis, thereby producing semiconductor elements having a desired shape in the singulation process similar to in the first to third embodiments.

In the foregoing, certain embodiments of the present invention have been described with reference to specific examples. The present invention, however, is not limited to these specific examples. All forms implementable by a person skilled in the art by suitably making design changes based on any of the embodiments of the present invention described above also fall within the scope of the present invention so long as they encompass the subject matter of the present invention. Furthermore, various modifications and alterations within the spirit of the present invention that could have been made by a person skilled in the art also fall within the scope of the present invention.

### REFERENCE NUMERALS

10—sapphire substrate
11—first face
12—second face
13, 13a, 13b—third face
20—semiconductor structure
CS—crystal plane
D1—first direction
D2—second direction
DS—dicing street
FL—focusing lens
IL1—first intersecting line
IL2—second intersecting line
LI—intensity distribution
Lr, Lr1, Lr2—light ray
MP—modified portion
Oa—central axis
W—wafer
Cr—crack

What is claimed is:

1. A method of manufacturing a semiconductor element, the method comprising:
a step of forming a modified portion inside a wafer comprising a sapphire substrate having a first face and a second face opposite the first face and a semiconductor structure disposed on the first face, the modified portion being formed inside the sapphire substrate along a first direction parallel to the second face by scanning a laser beam from a second face side along the first direction and focusing the laser beam inside the sapphire substrate; and
subsequent to the step of forming the modified portion, a step of severing and separating the wafer into a plurality of semiconductor elements; wherein:
in the step of forming the modified portion, the laser beam is focused to a position in a thickness direction of the sapphire substrate that is closer to the second face than to the first face;
the sapphire substrate has a crystal structure that includes a plurality of crystal planes along (10-14) or (10-11) planes;
an intensity distribution of the laser beam has an intensity peak in the first face of the sapphire substrate that is shifted from a center of the intensity distribution of the laser beam in a second direction intersecting the first direction, the second direction being, a direction, in a plan view, from (i) a given first point on a first intersecting line where the first face meets a third face along one of the plurality of crystal planes that is closest to being in parallel with the first direction towards (ii) a given second point on a second intersecting line where the third face meets the second face.

2. The method of manufacturing a semiconductor element according to claim 1 wherein the intensity distribution of the laser beam is adjusted by generating comatic aberration.

3. The method of manufacturing a semiconductor element according to claim 2 wherein the comatic aberration is controlled by the angle formed by the optical axis of a focusing lens and the incident-side laser beam rays.

4. The method of manufacturing a semiconductor element according to claim 1 wherein the second direction is orthogonal to the first direction.

5. The method of manufacturing a semiconductor element according to claim 2 wherein the second direction is orthogonal to the first direction.

6. The method of manufacturing a semiconductor element according to claim 3 wherein the second direction is orthogonal to the first direction.

7. The method of manufacturing a semiconductor element according to claim 1 wherein the second direction is orthogonal to the first intersecting line.

8. The method of manufacturing a semiconductor element according to claim 2 wherein the second direction is orthogonal to the first intersecting line.

9. The method of manufacturing a semiconductor element according to claim 3 wherein the second direction is orthogonal to the first intersecting line.

10. The method of manufacturing a semiconductor element according to claim 1 wherein the first direction is parallel to an a-axis of the sapphire substrate.

11. The method of manufacturing a semiconductor element according to claim 2 wherein the first direction is parallel to an a-axis of the sapphire substrate.

12. The method of manufacturing a semiconductor element according to claim 3 wherein the first direction is parallel to an a-axis of the sapphire substrate.

13. The method of manufacturing a semiconductor element according to claim 1 wherein the first direction is 45° oblique to an a-axis of the sapphire substrate.

14. The method of manufacturing a semiconductor element according to claim 2 wherein the first direction is 45° oblique to an a-axis of the sapphire substrate.

15. The method of manufacturing a semiconductor element according to claim 3 wherein the first direction is 45° oblique to an a-axis of the sapphire substrate.
